(19) United States
(12) Patent Application Publication
(10) Pub. No.: US 2004/0085795 A1
(43) Pub. Date: May 6, 2004

(54) Memory module and memory configuration with stub-free signal lines and distributed capacitive loads

(76) Inventors: Georg Braun, Holzkirchen (DE); Hermann Ruckerbauer, Moos (DE); Maksim Kuzmenka, Munchen (DE)

Correspondence Address: LERNER AND GREENBERG, P.A., POST OFFICE BOX 2480, HOLLYWOOD, FL, 33022-2480, US

(21) Appl. No.: 10/695,366

(22) Filed: Oct. 28, 2003

(30) Foreign Application Priority Data
Oct. 28, 2002 (DE) 102 50 156.4

(51) Int. Cl. G11C 5/02

(52) U.S. Cl. 365/51

(57) ABSTRACT

In a memory module for a memory configuration having a bus system made up of a plurality of signal lines, each signal line has respectively been produced essentially without any stub continuously from a supplying contact device to a discharging contact device, disposed close to the supplying contact device, in order to increase a maximum data transmission rate within the memory configuration. Between the supplying contact device and the discharging contact device, each of the signal lines is routed in succession at minimum distances via connection elements associated with the signal line on memory chips associated with the signal line.

### BACKGROUND OF THE INVENTION

### FIELD OF THE INVENTION

The invention relates to a memory module for a memory configuration having a bus system, made up of a plurality of signal lines, for transmitting data signals. The memory module has a substrate, a plurality of memory chips which are disposed on the substrate and are connected to the signal lines by connection elements, and contact devices which are respectively associated with one of the signal lines.

Modular electronic memory configurations for memory systems with variable configurations are normally provided with a system board having a slot or a plurality of slots for memory modules. The slots are filled with a respective memory module or remain unfilled, depending on the demands on the memory configuration or the level of expansion of the memory configuration.

An example of a memory system having a modular memory configuration is a computer system (PC, workstation, server) having an extendable main memory in which a system board is provided with slots for memory modules in the form of plug-in sockets, and the slots are filled with a variable number of memory modules, depending on the desired size of the main memory. The memory modules are usually in the form of single inline memory modules (SIMMs) or dual inline memory modules (DIMMs), whose mechanical and electrical interfaces to the system board are subject to industrial standards.

At relatively high clock and data transmission rates, the demands on the form of the signal lines in the bus system go up. Thus, data transmission rates of 667 Mbits per second and per data signal (Mbit/s/pin) are provided for double data rate (DDR) II memory systems for double data rate dynamic access memories (DDR-RAMs), and data transmission rates of up to 1.2 Gbit/s/pin are provided for DDRIII memory systems.

At these data transmission rates, the signal integrity of a data signal transmitted on one of the signal lines in the bus system is limited, inter alia, by a parasitic capacitance associated with the signal line. If the parasitic capacitance is too high, then signal line charges are not reversed quickly enough by a bus control chip or by memory chips disposed on the memory modules when there is a change in a level of the data signal. In addition, the signal integrity is impaired by reflection at interference points as clock rates increase.

A demanded high data transmission rate limits the maximum number of memory chips that can be provided in the memory configuration, since additional memory chips first result in relatively long line lengths in the bus system and also in a relatively high number of connections per signal line. This results in a relatively large capacitive load, in relatively long delay times and also in an increased noise signal level on account of a relatively large number of reflection points and interference. On the basis of present DDR-II configuration, for data transmission rates of up to 333 MHz/pin/s, just 64 memory chips are possible for memory systems without an error recognition device (error correction circuit (ECC)), and 72 memory chips are possible for memory systems with an error recognition device. By contrast, in slower conventional single data rate (SDR) memory systems or those based on the DDRI standard, 128 memory chips are possible for memory systems without an error recognition device and 144 memory chips are possible for memory systems with an error recognition device.

To increase the storage density of a memory configuration for a constant data transmission rate, it is known practice, for example from DDRI memory systems, to use buffer chips for signal conditioning in order to maintain the signal integrity between the buffer chips and the signal lines in the bus system. Since the signal lines in the bus system are then no longer connected to all the memory chips disposed on the memory modules, but rather are now connected just to one buffer chip per memory module, the capacitive load on the signal lines which is represented by a memory module and the number of interference points are reduced.

A drawback of this solution is the need for a wait cycle (latency) between the transmission of control and address signals on the control and address signal lines, on the one hand, and the transmission of data on data signal lines on the other. In the case of a write cycle, the control and address signals are first transmitted to a buffer or temporary store and only in a subsequent cycle are they transmitted, together with the data signals output with a delay of one cycle, to the memory chips. Such a wait cycle significantly reduces the data transmission rate, particularly in the case of random address access. In addition, the buffers or temporary stores increase the space requirements and cost of the memory system.

Another proposed solution is to dispose two or more respective memory chips within a chip package (chip stacking). This involves respectively routing corresponding connections on the at least two memory chips to a common connection on the chip package. The memory chips disposed in a common chip package are selectively addressed using separately routed chip select (CS) signals.

A drawback of the proposed solution for increasing the memory size of a memory configuration is that chip stacking is a relatively new and expensive process in the case of fine-pitch ball grid array (FBGA) packages, which are usual for memory chips for DDRII memory systems. Another problem is presented by suitable cooling for the memory chips stacked in the chip package. In addition, a capacitive load represented by a respective memory chip disadvantageously arises in respective paired concentrations on the signal lines in the bus system. A locally concentrated, comparatively high capacitance acts as an interference point for radio-frequency data signals.

Another conceivable solution is to provide eight slots on the system board instead of four, in line with usual industrial standards. Apart from significantly lengthened signal lines, this solution is not suitable for applications where space is limited, on account of the increased space requirement on the system board. In addition, the slots are usually in the form of respective plug connections. Each additional plug connection in a memory configuration significantly reduces the reliability of the overall system, and therefore increasing the number of plug connections rules out using computer systems with high demands on reliability, such as servers.

### SUMMARY OF THE INVENTION

It is accordingly an object of the invention to provide a memory module and a memory configuration with stub-free signal lines and distributed capacitive loads that overcomes the above-mentioned disadvantages of the prior art devices of this general type, which, even without additional signal conditioning devices, ensures a high data transmission rate as compared with currently known memory configurations while providing a high level of reliability. It is also an object of the invention to provide a memory configuration that is formed from memory modules.

The inventive memory module for a memory configuration has a bus system, made up of a plurality of signal lines, for transmitting data signals. The memory module further has a substrate, a plurality of memory chips which are disposed on the substrate and are connected to the signal lines through connection elements, and also a supplying contact device and a discharging contact device, respectively, for each signal line. In this case, the respective supplying and discharging contact devices associated with one another are disposed physically close together.

Providing a discharging contact device allows the signal lines to be advantageously routed past the associated memory chips.

Without a discharging contact device, each signal line routed to the memory module forms a stub at which reflections produce noise signals that limit a maximum data transmission rate for the memory system.

If the contact devices each have more than two associated memory chips on the memory module, then contact devices which are associated with one another are disposed physically close together and the distance between the two contact devices is shorter than the mean distance between the memory chips associated with the contact devices and the supplying contact device. If, by contrast, the contact devices are connected to just one memory chip or to precisely two memory chips, then they are considered to be disposed physically close together if a maximum of sixteen different contact devices are disposed between the discharging contact device and the associated supplying contact device, regardless of whether the supplying contact device and the associated discharging contact device are disposed on the same substrate surface or on opposing substrate surfaces. Advantageously, the contact devices associated with one another are isolated from one another by a maximum of one or two contact devices that are respectively associated with shielding lines.

The configuration of supplying and discharging contact devices which are respectively associated with one another so as to be physically close together, in conjunction with suitable placement of the memory chips on the memory module, allows a particularly advantageous, short form for the signal lines. Advantageously, each signal line in the configuration has respectively been produced essentially without any stub continuously and on a direct path from the supplying contact device to the discharging contact device. Between the supplying contact device and the discharging contact device, it is routed in succession via all the connection elements associated with the signal line on the memory chip associated with the signal line.

A signal line in such a form essentially has no or just very short stubs formed almost exclusively by the connection elements on the memory modules. Every stub termination forms a reflection point at which a data signal transmitted on the signal line is reflected. The reflected signal is overlaid on the data signal. If a path length for a stub is sufficiently short in respect of a bit frequency for the data signal, then any distortion of the data signal by the reflected signal is small. By avoiding or shortening stubs, it is advantageously possible to increase the data transmission rate in a memory configuration having memory modules in the inventive form.

If the contact devices are disposed in contact arrays, then respective supplying and discharging contact devices associated with one another are advantageously disposed immediately adjacent to one another. If the memory chips associated with the contact devices are now disposed on both sides and essentially at right angles to the contact array, S then the associated signal line on the memory module can also be very short. It is then routed, by way of example, from the supplying contact device in a direction at right angles to the contact array essentially in a straight line in succession to the associated memory chips disposed on a first surface of the substrate, via a plated-through hole to the other surface, and back to the supplying contact device, again essentially in a straight line and via a further plated-through hole. The signal line has no significant portion parallel to the contact array and is therefore advantageously short. In general, short signal lines have short delay times relative to long signal lines and allow higher data transmission rates.

If the contact devices are disposed in at least two contact arrays disposed directly opposite one another or offset from one another on the substrate, then respective supplying and discharging contact devices associated with one another are advantageously disposed so as to be directly opposite or offset from one another. There is no through plating. When the inventive memory module is provided on the system board, the routing of signal lines to and from the memory module is simplified.

In both embodiments of the inventive memory module, respective supplying and discharging contact devices associated with one another are directly adjacent to one another or are opposite one another essentially directly or with an offset. Within the context of the present invention, however, the associated contact devices are also disposed physically close together when a small number of further contact devices is disposed between the associated contact devices. Possible further contact devices are, by way of example, also one or two contact devices for routing shielding lines associated with the signal lines to the memory module.

To shorten the signal lines further, the memory chips can be provided on the two surfaces of the substrate in various component packages with connection assignments mirrored in respect of one another.

Preferably, the signal lines on and/or in the substrate are routed such that connections between the connection elements and the signal line are disposed at largely regular distances. In this case, the distances essentially correspond at least to dimensions of a component package, for example for an FBGA, on the memory chips. The capacitive loading of the signal line formed by the memory modules is thus advantageously distributed in the manner of a capacitive covering, as a result of which characteristic impedance for the signal line is reduced and a higher maximum data transmission rate within the memory configuration made possible.

Preferably, the signal lines therefor are connected to the associated connection elements at equidistant intervals.

A memory module in accordance with the invention can be produced using various types of memory chips, for example using single data rate dynamic random access memories (SDR-DRAMs). Preferably, however, memory chips having a DDR interface to the configuration are provided on the memory module. Since data transfer in DDR-DRAMs takes place both on a positive and on a negative edge of a data clock signal, a data transmission rate which is almost twice that of SDR-DRAMs is made possible for the same frequency of the data clock signal.

In comparison with DDR memory systems (produced using known memory modules) without error correction devices, the inventive memory module increases the maximum possible number of memory chips in the memory system to 128.

In comparison with DDR memory systems (produced using known memory modules) with error correction devices, the inventive memory module increases the maximum possible number of memory chips in the memory system to 144.

To allow a corresponding number of memory chips to be disposed on the substrate of the memory module in current standardized component packages such as FBGA, it is necessary to enlarge the surface of the substrate. The enlarged surface of the substrate also improves cooling for the memory module.

In line with a first preferred embodiment of the inventive memory module, the substrate surface is enlarged by dividing the substrate into at least two substrate sections. In this case, the substrate sections are preferably each disposed at a distance of between 5 to 25 mm and are oriented parallel. The substrate sections are connected to one another by arrays of plug contacts, a flexible conductive tape or by boards in this configuration.

In line with another preferred embodiment of the inventive memory module, the substrate is in the form of a rectangular printed circuit board, the memory chips being disposed in at least two rows in a respective parallel orientation on two opposing surfaces of the printed circuit board.

In this case, dimensions of 1.7 to 3.0 inches×5.25 inches are obtained for the printed circuit board for an inventive, standardized memory module with DDR-DRAMs. In comparison to the usual dimensions of 1.2 inches×5.25 inches in line with the JEDEC standard, approximately twice the installation height is obtained in the computer system.

The inventive memory modules can be used to produce a memory configuration which, besides at least one memory module in accordance with the invention, has a system board, at least one holding device which is disposed on the system board and is suitable for holding memory modules, and a bus control chip which is connected to at least one of the holding devices.

Preferably, the memory configuration has precisely four holding devices that are in the form of plug-in sockets. Therefor, the memory configuration meets existing industrial standards regarding space requirement on a system board in a computer system.

Ordinary bus systems have 16, 32, 64 or more signal lines for synchronously transmitting data signals. If the memory modules are provided with respective supplying and discharging contact devices for 64 signal lines and, by way of example, additionally respective contact devices for shielding lines, then 256 contact devices need to be provided on the memory module for the data bus alone. Such a number of contact devices can be implemented only with extreme difficulty within the context of the prescribed industrial standards for the mechanical and electrical interfaces of memory modules.

The invention therefore provides for a bus system that has a multiple X of a number Y of signal lines allocated per memory module to be fractionated. To this end, each memory module is associated with one of X memory module groups. Each signal line in the bus system is then just respectively associated with the memory modules in precisely one of the X memory module groups.

In line with the invention, two memory module groups are provided for a 64-bit bus system for example, with 32 respective signal lines in the bus system being routed to the memory module groups.

Other features which are considered as characteristic for the invention are set forth in the appended claims.

Although the invention is illustrated and described herein as embodied in a memory module and a memory configuration with stub-free signal lines and distributed capacitive loads, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic, cross-sectional view through a memory configuration with memory modules based on a first exemplary embodiment in accordance with the invention; and

FIG. 2 is a diagrammatic, cross-sectional view through the memory configuration with the memory modules based on a second exemplary embodiment in accordance with the invention.

### DESCRIPTION OF THE PREFERRED EMBODIMENTS

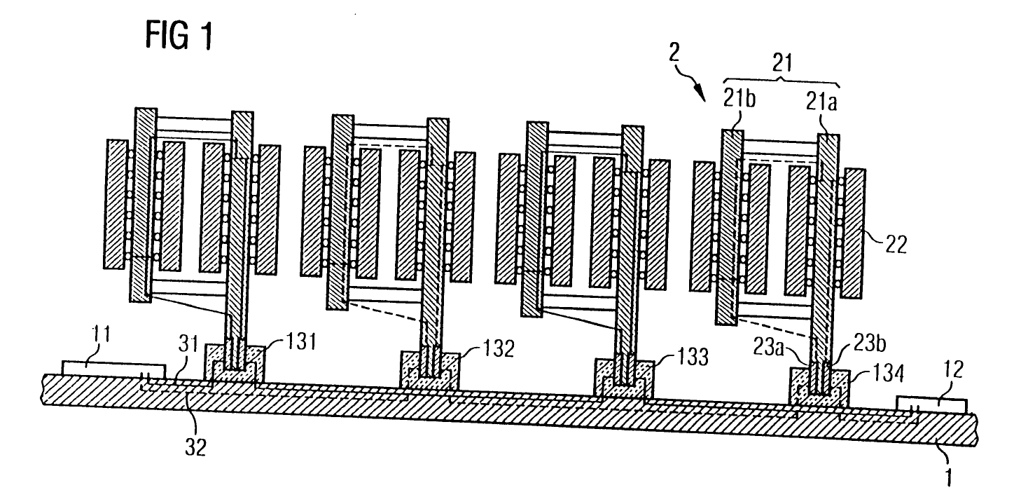

Referring now to the figures of the drawing in detail and first, particularly, to FIG. 1 thereof, there is shown schematically a memory configuration that contains a bus control chip 11, a terminating device 12 and four holding devices 131-134, which are in the form of plug-in sockets, for holding memory modules 2. In this case, the bus control chip 11, the terminating device 12 and the plug-in sockets 131-134 are respectively disposed on a surface of a system board 1. On the memory modules 2, memory chips 22 are disposed on a first 21a and a second 21b substrate section. The two substrate sections 21a, 21b are connected to one another electrically and mechanically. The memory modules 2 in the first 131 and third 133 plug-in sockets are associated with the first memory module group, and the memory modules 2 in the second 132 and fourth 134 plug-in sockets are associated with the second memory module group.

By way of representation of the signal lines in a bus system in the memory configuration, a first signal line 31, associated with the first memory module group, and a second signal line 32, associated with the second memory module group, are shown. Each signal line 31, 32 is routed in or on the system board 1 from the bus control chip 11 to a supplying contact device 23a in the memory module 2 disposed in the respective first plug-in socket 131, 132 in the respective memory module group, and in and/or on the memory module 2 to a discharging contact device 23b in the memory module 2, in the same way to the respective further plug-in socket 133, 134 in the memory module group, and from the respective further plug-in socket 133, 134 to the terminating device 12.

The first signal line 31 has four respective associated memory chips 22 on the memory modules 2 in the configuration shown. The signal line 31 is looped through both on the two substrate sections 21a, 21b of the memory module 2 and on the system board 1 essentially continuously with just short stubs to respective memory chips 22 disposed in opposing fashion on the substrate 21, which memory chips can have a respective mirrored connection assignment.

The memory configuration shown allows operation of 128, or, when error correction devices are used, 144 memory chips 22 on just four slots 131, 132, 133, 134 and, as a result of the described form of the signal lines 31, 32, simultaneously ensures the demanded high data transmission rates of, by way of example, 670 Mbit/pin/s.

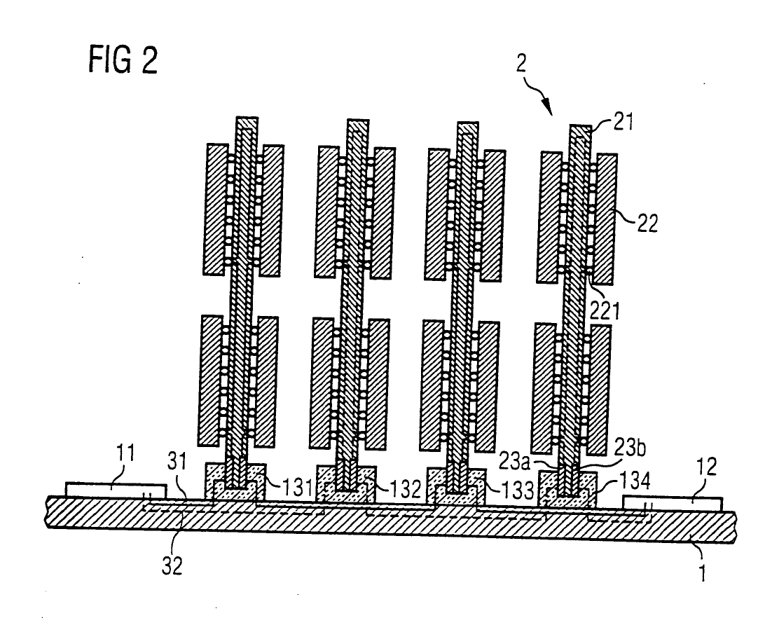

FIG. 2 shows a further memory configuration having different memory modules 2 with approximately twice the size of the substrate 21 as compared with conventional memory modules. In contrast to the memory modules 2 known from FIG. 1, a signal line 31 needs to be routed on the memory module 2 without any stub in succession to connection elements 221 associated with the signal line 31 on the memory chips 2. Since just one respective connection element 221 per memory chip 22 is connected to the signal line 31 locally, a high concentration of parasitic input capacitances is avoided on the signal line 31 and a further-increased data transmission rate is made possible. In addition, the distributed configuration of the memory chips 22 increases the effectiveness of the cooling on all the memory chips 22. Any overheating of the memory chips 22, which is entirely critical at the demanded data transmission rates, is prevented.

We claim:

1. A memory module for a memory configuration having a bus system with a plurality of signal lines for transmitting data signals, the memory module comprising:
a substrate;
connection elements supported by said substrate;
a plurality of memory chips disposed on said substrate and connected to the signal lines through said connection elements; and
contact devices, including supplying contact devices and discharging contact devices, each of the signal lines being connected to a respective one of said supplying contact devices and a respective one of said discharging contact devices, said respective supplying and discharging contact devices associated with one another being disposed physically close together.

2. The memory module according to claim 1, wherein said contact devices have at least three associated said memory chips, each of said discharging contact devices is disposed at a shorter distance from an associated said respective supplying contact device than, on average, said connection elements associated with the signal line on said memory chips associated with the signal line.

3. The memory module according to claim 1, wherein said contact devices are associated with precisely one of said memory chips, and said respective supplying contact device and an associated said respective discharging contact device have a maximum of sixteen different one of said contact devices disposed between them.

4. The memory module according to claim 1, wherein each respective one of the signal lines is routed essentially without any stub continuously and on a direct path from said respective supplying contact device in succession via said connection elements associated with the respective signal line on said memory chips associated with the respective line to said respective discharging contact device.

5. The memory module according to claim 1, wherein said contact devices are disposed in at least one contact row, and in said contact row there is a maximum of two further ones of said contact devices provided between each said respective supplying contact device and an associated said respective discharging contact device.

6. The memory module according to claim 1, wherein said contact devices are disposed in at least two contact rows which are disposed one of directly opposite one another and offset from one another on said substrate, and each of said supplying contact devices is disposed opposite an associated said respective discharging contact device directly or with an offset.

7. The memory module according to claim 1, wherein:
said memory chips have a chip package with a given length and a given width; and
said connection elements associated with a respective signal line are connected to the respective signal line at a respective distance which is obtained from said given length or from said given width of said chip package for said memory chips.

8. The memory module according to claim 1, wherein said connection elements associated with a respective one of the signal lines are connected to the respective signal line substantially at equivalent distances.

9. The memory module according to claim 1, wherein said memory chips each have a double data rate interface.

10. The memory module according to claim 1, wherein the memory module holds up to 32 of said memory chips for a memory system without error correction devices which contains the memory configuration.

11. The memory module according to claim 1, wherein the memory module holds up to 36 of said memory chips for a memory system with error correction devices which contains the memory configuration.

12. The memory module according to claim 1, wherein said substrate has at least two substrate sections which are mechanically and electrically connected to one another.

13. The memory module according to claim 12, wherein said substrate sections are disposed at a distance of between 5 and 25 mm, respectively, and are oriented parallel to one another.

14. The memory module according to claim 1, wherein said substrate is a rectangular printed circuit board, and said memory chips are disposed in at least two rows in a respective parallel orientation on two opposing surfaces of said rectangular printed circuit board.

15. The memory module according to claim 14, wherein said rectangular printed circuit board has dimensions 1.7 to 3.0 inches×5.25 inches.

16. The memory module according to claim 1, wherein said contact devices are associated with precisely two of said memory chips, and each of said supplying contact devices and an associated said respective discharging contact device have a maximum of sixteen different ones of said contact devices disposed between them.

17. The memory module according to claim 1, wherein said contact devices have at least three associated ones of said memory chips, each of said discharging contact devices is respectively disposed at a shorter distance from an associated said respective supplying contact device than, an average distance between said memory chips.

18. A memory configuration for a memory system, the memory configuration comprising:
a system board;
a bus system having a plurality of signal lines for transmitting data signals and supported by said system board;
holding devices disposed on said system board;
a bus control chip connected to said holding devices; and
memory modules disposed and held by said holding devices, each of said memory modules including:
a substrate;
connection elements supported by said substrate;
a plurality of memory chips disposed on said substrate and connected to said signal lines through said connection elements; and
contact devices, including supplying contact devices and discharging contact devices, each of said signal lines connected to a respective one of said supplying contact devices and a respective one of said discharging contact devices, said respective supplying contact device and said respective discharging contact device associated with one another being disposed physically close together.

19. The memory configuration according to claim 18, wherein said holding devices are precisely four holding devices configured as plug-in sockets.

20. The memory configuration according to claim 18, wherein said bus system contains a multiple X of a number Y of said signal lines assigned for each of said memory modules, each of said memory modules is associated with one of X memory module groups, and each of said signal lines is respectively associated with said memory modules in one of said X memory module groups.

21. A memory module for a memory configuration having a bus system with a plurality of signal lines for transmitting data signals, the memory module comprising:
a substrate;
connection elements supported by said substrate;
a plurality of memory chips disposed on said substrate and connected to the signal lines through said connection elements; and
contact devices, including supplying contact devices and discharging contact devices, each of the signal lines connected to a respective one of said supplying contact devices and a respective one of said discharging contact devices, each respective one of the signal lines being routed substantially without any stub continuously and on a direct path from said respective supplying contact device in succession through said connection elements associated with the respective signal line on said memory chips associated with the respective signal line to said respective discharging contact device, and said contact devices disposed in at least one contact row and, in said contact row, said respective supplying contact device and an associated said respective discharging contact device have a maximum of two further ones of said contact devices provided between them.

22. The memory module according to claim 21, wherein no further ones of said contact devices are disposed between said respective supplying contact device and said respective discharging contact device.

23. A memory module for a memory configuration having a bus system with a plurality of signal lines for transmitting data signals, the memory module comprising:
a substrate;
connection elements supported by said substrate;
a plurality of memory chips disposed on said substrate and connected to the signal lines through said connection elements; and
contact devices, including supplying contact devices and discharging contact devices, each of the signal lines connected to a respective one of said supplying contact devices and a respective one of said discharging contact devices, each respective one of the signal lines being routed substantially without any stub continuously and on a direct path from said respective supplying contact device in succession through said connection elements associated with the respective signal line on said memory chips associated with the respective signal line to said respective discharging contact device, and said contact devices being disposed in two contact rows disposed opposite one another on said substrate directly or with an offset, and each of said supplying contact devices being disposed opposite an associated said respective discharging contact device directly or with an offset.
